(19) United States
(12) Patent Application Publication
(10) Pub. No.: US 2026/0113908 A1
(43) Pub. Date: Apr. 23, 2026

(54) SERVER TEMPERATURE CONTROL METHOD, SYSTEM AND DEVICE, AND STORAGE MEDIUM

(71) Applicant: SUZHOU METABRAIN INTELLIGENT TECHNOLOGY CO., LTD., Suzhou, Jiangsu (CN)

(72) Inventors: Jenhui WENG, Suzhou, Jiangsu (CN); Yongqi ZHU, Suzhou, Jiangsu (CN)

(21) Appl. No.: 19/487,945

(22) PCT Filed: Sep. 29, 2024
(86) PCT No.: PCT/CN2024/122233

§ 371 Date: Nov. 25, 2025

(30) Foreign Application Priority Data
Jan. 17, 2024 (CN) 202410066855.8

(51) Int. Cl. H05K 7/20; G06F 9/48

(52) U.S. Cl. CPC H05K 7/20836; G06F 9/4893

(57) ABSTRACT

The present application discloses a method, system and device for controlling temperature of a server, and a storage medium, applied in the technical field of server controlling, which solves the problem in conventional solutions that the temperature controlling over servers is not ideal. The method includes: after the server has been powered on, by a parallel processing device, determining respective component types of all of components of a quantity N and sending the respective component types to a baseboard management controller; at a first stage of each of parameter-reading periods, reading simultaneously respective temperature data of the components of the quantity N by using threads of the quantity N of the parallel processing device in a parallel-reading mode; at a second stage, sending the temperature data of the components the component types of which are a graphics processor to the baseboard management controller; and at a third stage, sending the temperature data of the components the component types of which are not a graphics processor to the baseboard management controller, whereby the baseboard management controller controls the temperature of the server based on the respective temperature data of the components of the quantity N. By applying the solutions of the present application, the temperature controlling over the server may be realized more precisely and effectively.

### CROSS-REFERENCE TO RELATED APPLICATION

The present application claims the priority of the Chinese patent application filed on Jan. 17, 2024 before the Chinese Patent Office with the application number of 202410066855.8 and the title of “SERVER TEMPERATURE CONTROL METHOD, SYSTEM AND DEVICE, AND STORAGE MEDIUM”, which is incorporated herein in its entirety by reference.

### FIELD

The present application relates to the technical field of server controlling, and particularly relates to a method, system and device for controlling temperature of a server, and a storage medium.

### BACKGROUND

Generally, in the heat dissipation of a server, usually a BMC (Board Management Controller, or baseboard management controller) is used to poll the components by using an I2C (Inter-Integrated Circuit, or two-wire serial bus) in an Out-of-Band mode, thereby obtaining the parameter values of the peripheral components.

Referring to FIG. 1, FIG. 1 is a schematic diagram of the design of a conventional server. The BMC in FIG. 1, via 2 two-wire-serial-bus switch chips (I2C Switch), may access totally 11 PCIe (Peripheral Component Interconnect express, or high-speed serial computer expansion-bus standard) cards, which are labeled in FIG. 1 sequentially as PCIe card 0 to PCIe card 10. If it is required to cost 100 to 300 milliseconds to read the temperature datum of each of the PCIe cards (different components might have different time consumptions), then the reading by the BMC on the temperature data of all of the PCIe cards at the back panel in FIG. 1 requires 1.1 seconds to 3.3 seconds, which is a long time consumption. Furthermore, in practical applications, servers have increasingly higher internal densities, and increasingly higher quantities of the internal components, and a BMC might be required to poll several blocks. After all of them have been polled, the overall time consumption might be 3 seconds to 5 seconds or even more. If some of the components are components having a high temperature sensitivity, timely and precise controlling over the temperatures probably cannot be done, which causes that those components have quick temperature rises, and accordingly it is required to adjust to obtain a higher fan power to cool them. Therefore, a case easily happens of a higher fan noise, a higher energy consumption, frequent fan fluctuation and a shortened fan life, which finally affects the service life and the reliability of the server.

In conclusion, how to realize the temperature controlling over the server more precisely and effectively, to ensure the service life and the reliability of the server, is a technical problem required to be solved urgently by a person skilled in the art currently.

### SUMMARY

An object of the present application is to provide a method, system and device for controlling temperature of a server, and a storage medium, so as to realize the temperature controlling over the server more precisely and effectively, to ensure the service life and the reliability of the server.

In order to solve the above technical problem, the present application provides the following technical solutions:

A method for controlling temperature of a server, wherein a baseboard management controller is connected to a predetermined parallel processing device, the parallel processing device is connected to components of a quantity N, and the method for controlling the temperature of the server is applied in the parallel processing device, and comprises:
after the server has been powered on, determining respective component types of all of the components of the quantity N and sending the respective component types to the baseboard management controller:
at a first stage of each of parameter-reading periods, reading simultaneously respective temperature data of the components of the quantity N by using threads of the quantity N of the parallel processing device in a parallel-reading mode:
at a second stage of each of the parameter-reading periods, sending the temperature data of the components the component types of which are a graphics processor to the baseboard management controller; and
at a third stage of each of the parameter-reading periods, sending the temperature data of the components the component types of which are not a graphics processor to the baseboard management controller, whereby the baseboard management controller controls the temperature of the server based on the respective temperature data of the components of the quantity N.

In some embodiments, the parallel processing device comprises one single first controller having at least threads of the quantity N.

In some embodiments, the first controller has a first interface and a second interface that are for connecting the baseboard management controller:
the step of, at the second stage of each of the parameter-reading periods, sending the temperature data of the components the component types of which are a graphics processor to the baseboard management controller comprises:
at the second stage of each of the parameter-reading periods, via the first interface of the first controller, sending the temperature data of the components the component types of which are a graphics processor to the baseboard management controller; and
the step of, at the third stage of each of the parameter-reading periods, sending the temperature data of the components the component types of which are not a graphics processor to the baseboard management controller comprises:
at the third stage of each of the parameter-reading periods, via the second interface of the first controller, sending the temperature data of the components the component types of which are not a graphics processor to the baseboard management controller.

In some embodiments, among the components of the quantity N, the component types other than a graphics processor have a quantity of K, wherein K is a positive integer not less than 2, and the third stage of each of the parameter-reading periods is divided into sub-stages of the quantity K, wherein i is a positive integer and 1≤i≤K; and
the step of, at the third stage of each of the parameter-reading periods, via the second interface of the first controller, sending the temperature data of the components the component types of which are not a graphics processor to the baseboard management controller comprises:
at an i-th sub-stage of the third stage of each of the parameter-reading periods, via the second interface of the first controller, sending the temperature datum of an i-th type of the components the component types of which are not a graphics processor to the baseboard management controller.

In some embodiments, the parallel processing device comprises second controllers of a quantity M, a total quantity of threads that the second controllers of the quantity M have is greater than or equal to N, wherein M is a positive integer not less than 2, any one of the second controllers is connected to at least one instance of the components of the quantity N. and any one instance of the components of the quantity N is connected to at most one instance of the second controllers.

In some embodiments, all of device models of the second controllers of the quantity M are the same, each of the second controllers has threads of a quantity a, wherein a is a positive integer and a×M≥N, and each of the second controllers has a first interface and a second interface that are for connecting the baseboard management controller.

In some embodiments, the step of, at the first stage of each of the parameter-reading periods, reading simultaneously the respective temperature data of the components of the quantity N by using the threads of the quantity N of the parallel processing device in the parallel-reading mode comprises:
at the first stage of each of the parameter-reading periods, by each of the second controllers, reading simultaneously the respective temperature data of the components connected to the second controller by using the threads of the quantity a of the second controller in the parallel-reading mode.

In some embodiments, the second stage is divided into sub-stages of the quantity M. and j is a positive integer and 1≤j≤M; and
the step of, at the second stage of each of the parameter-reading periods, sending the temperature data of the components the component types of which are a graphics processor to the baseboard management controller comprises:
at a j-th sub-stage of the second stage of each of the parameter-reading periods, by a j-th second controller among the second controllers of the quantity M, via the first interface of the j-th second controller, sending the temperature data of the components the component types of which are a graphics processor that are connected to the j-th second controller to the baseboard management controller.

In some embodiments, among the components of the quantity N, the component types other than a graphics processor have a quantity of K, wherein K is a positive integer not less than 2, the third stage of each of the parameter-reading periods is divided into rounds of the quantity K, and each of the rounds is divided into sub-stages of the quantity M, wherein i is a positive integer and 1≤i≤K, and j is a positive integer and 1≤j≤M; and
the step of, at the third stage of each of the parameter-reading periods, sending the temperature data of the components the component types of which are not a graphics processor to the baseboard management controller comprises:
at a j-th sub-duration of an i-th round of the third stage of each of the parameter-reading periods, by a j-th second controller among the second controllers of the quantity M, via the second interface of the j-th second controller, sending the temperature datum of an i-th type of the components the component types of which are not a graphics processor that are connected to the j-th second controller to the baseboard management controller.

In some embodiments, the parallel processing device is a parallel processing device based on a micro-controlling unit, or is a parallel processing device based on a Field-Programmable Gate Array, or is a parallel processing device based on a Complex Programmable Logic Device.

In some embodiments, the method further comprises:
in response to a failure signal sent by any one of the components having been received, pausing the sending of the temperature data of a current stage, sending the failure signal to the baseboard management controller, and after the sending of the failure signal has been completed, continuing the sending of the temperature data of the current stage.

A system for controlling temperature of a server, wherein the system comprises a baseboard management controller and a predetermined parallel processing device connected to the baseboard management controller, the parallel processing device is connected to components of a quantity N, and the parallel processing device comprises:
a powering-on detecting module configured for, after the server has been powered on, determining respective component types of all of the components of the quantity N and sending the respective component types to the baseboard management controller:
a first-stage executing module configured for, at a first stage of each of parameter-reading periods, reading simultaneously respective temperature data of the components of the quantity N by using threads of the quantity N of the parallel processing device in a parallel-reading mode:
a second-stage executing module configured for, at a second stage of each of the parameter-reading periods, sending the temperature data of the components the component types of which are a graphics processor to the baseboard management controller; and a third-stage executing module configured for, at a third stage of each of the
parameter-reading periods, sending the temperature data of the components the component types of which are not a graphics processor to the baseboard management controller, whereby the baseboard management controller controls the temperature of the server based on the respective temperature data of the components of the quantity N.

A device for controlling temperature of a server, wherein the device comprises:
a memory configured for storing a computer program; and
a processor configured for executing the computer program to implement the steps of the method for controlling the temperature of the server stated above.

A computer-readable storage medium, wherein the computer-readable storage medium stores a computer program, and the computer program, when executed by a processor, implements the steps of the method for controlling the temperature of the server stated above.

A method for controlling temperature of a server, wherein a baseboard management controller is connected to a predetermined parallel processing device, the parallel processing device is connected to components of a quantity N, and the method for controlling the temperature of the server is applied in the baseboard management controller, and comprises:
after the server has been powered on and the parallel processing device has determined respective component types of all of the components of the quantity N, receiving the respective component types of the components of the quantity N sent by the parallel processing device:
at a second stage of each of parameter-reading periods, receiving temperature data of the components the component types of which are a graphics processor sent by the parallel processing device:
at a third stage of each of the parameter-reading periods, receiving temperature data of the components the component types of which are not a graphics processor sent by the parallel processing device; and
controlling the temperature of the server based on the respective temperature data of the components of the quantity N;
wherein at a first stage of each of the parameter-reading periods, the parallel processing device reads simultaneously the respective temperature data of the components of the quantity N by using threads of the quantity N of the parallel processing device in a parallel-reading mode.

### BRIEF DESCRIPTION OF THE DRAWINGS

In order to more clearly illustrate the technical solutions of the embodiments of the present application or the prior art, the figures that are required to describe the embodiments or the prior art will be briefly described below. Apparently, the figures that are described below are merely embodiments of the present application, and a person skilled in the art can obtain other figures according to these figures without paying creative work.

FIG. 1 is a schematic diagram of the design of a conventional server;

FIG. 2 is a schematic structural diagram of a system for controlling temperature of a server according to a particular embodiment of the present application;

FIG. 3 is a flow chart of the implementation of a method for controlling temperature of a server according to the present application when applied in a parallel processing device;

FIG. 4 is a schematic structural diagram of a parallel processing device according to a particular embodiment of the present application;

FIG. 5 is a schematic structural diagram of a parallel processing device according to another particular embodiment of the present application;

FIG. 6 is a schematic structural diagram of the modules of a parallel processing device according to another particular embodiment of the present application;

FIG. 7 is a schematic structural diagram of a device for controlling temperature of a server according to a particular embodiment of the present application;

FIG. 8 is a schematic structural diagram of a computer-readable storage medium according to the present application; and

FIG. 9 is a flow chart of the implementation of a method for controlling temperature of a server according to the present application when applied in a baseboard management controller.

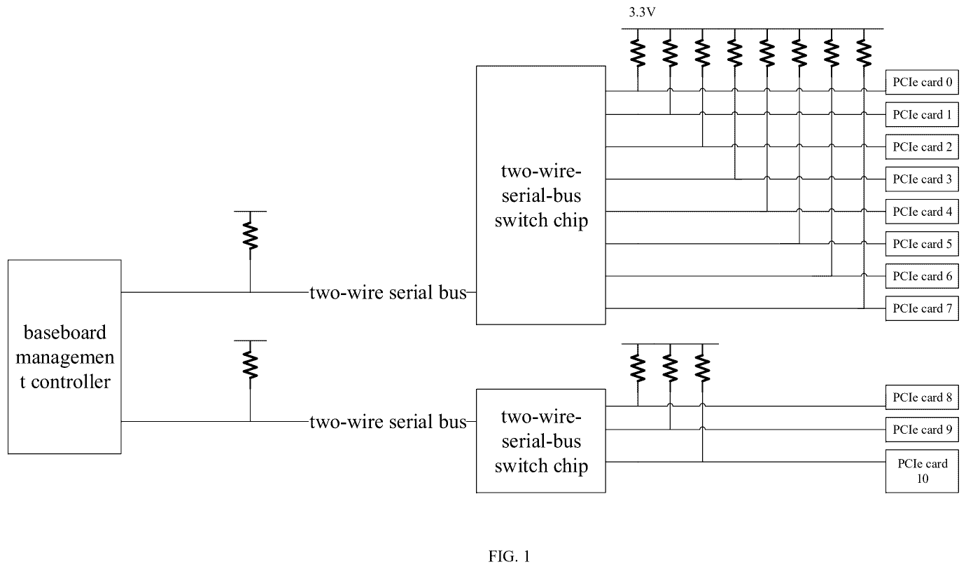

### DETAILED DESCRIPTION

The core of the present application is to provide a method for controlling temperature of a server, which may effectively shorten the time consumption on the acquirement of the temperature data of the components by the baseboard management controller, and may timely acquire the temperature datum of the graphics processor, which has a high temperature sensitivity. Therefore, the solutions of the present application may realize the temperature controlling over the server more precisely and effectively, to ensure the service life and the reliability of the server.

In order to enable a person skilled in the art to better comprehend the solutions of the present application, the present application will be described in further detail below with reference to the drawings and the particular embodiments. Apparently, the described embodiments are merely certain embodiments of the present application, rather than all of the embodiments. All of the other embodiments that a person skilled in the art obtains on the basis of the embodiments of the present application without paying creative work fall within the protection scope of the present application.

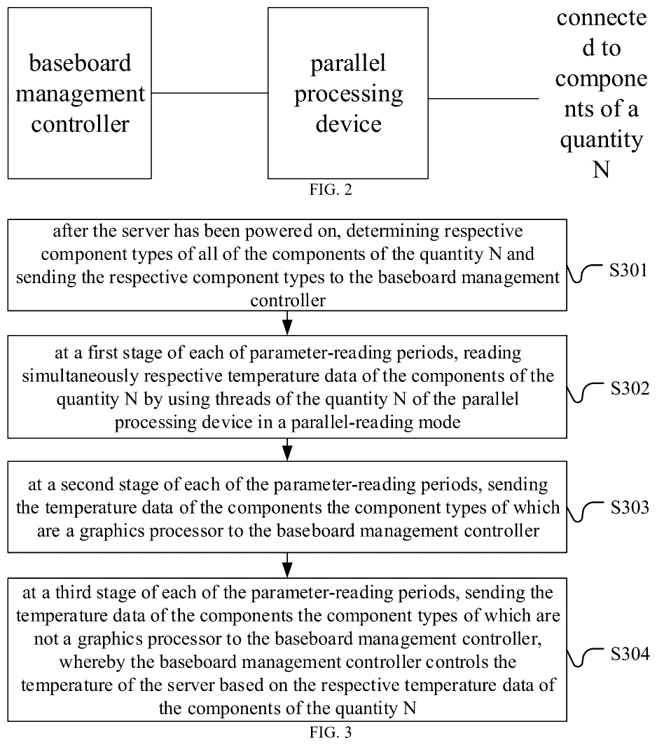

Referring to FIG. 2, FIG. 2 is a schematic structural diagram of a system for controlling temperature of a server according to a particular embodiment of the present application. The system for controlling temperature of a server comprises a baseboard management controller and a parallel processing device. In FIG. 2, the baseboard management controller is connected to the predetermined parallel processing device, and the parallel processing device is connected to components of a quantity N. Referring to FIG. 3, FIG. 3 is a flow chart of the implementation of the method for controlling temperature of a server according to the present application. Furthermore, the method for controlling temperature of a server may be applied in the parallel processing device, and comprises the following steps:

Step S301: after the server has been powered on, determining respective component types of all of the components of the quantity N and sending the respective component types to the baseboard management controller.

Because, in the solutions of the present application, subsequently, according to the different component types, the temperature data of the components of the different types are sent sequentially from the parallel processing device to the baseboard management controller, it is required to firstly determine the respective component types of the components of the quantity N.

The step S301 is merely required to be executed one time after the server has been powered on. In other words, within all of the subsequent parameter-reading periods, the baseboard management controller has already known the respective component types of the components of the quantity N. Certainly, in a fewer occasions, the case of component updating happens; for example, one GPU (Graphics Processing Unit, or graphics processor) is newly added at a certain slot of a certain back panel of the server. Accordingly, usually the operation of inserting the new component is performed after the server is powered off. Certainly, if in the fewer occasions hot-line work is allowed, then it is merely required to execute the step S301 one time after the component updating.

The components of the quantity N described herein are usually all PCIe cards provided at the back panel. The parallel processing device also may be provided at the back panel. Certainly, in some occasions the server might have multiple back panels, and for each of the back panels, the solutions of the present application may be applied, whereby the baseboard management controller may realize the quick reading of the temperature data of the components based on the parallel processing devices provided at the back panels. For example, in some occasions, the server has a front-window hard-disk back panel, a built-in SSD (Solid State Disk) back panel, a front-window expansion board, a rear-window PCIe-card back panel, and so on.

After the server has been powered on, the baseboard management controller may, by using the parallel processing device, poll the components of the quantity N connected to the parallel processing device, thereby determining the respective component types of all of the components of the quantity N.

Step S302: at a first stage of each of parameter-reading periods, reading simultaneously respective temperature data of the components of the quantity N by using threads of the quantity N of the parallel processing device in a parallel-reading mode.

At the first stage of each of the parameter-reading periods, the parallel processing device reads simultaneously the respective temperature data of the components of the quantity N by using threads of the quantity N of the parallel processing device in a parallel-reading mode. As a result, even if N is a large numerical value, the time consumption at the first stage of the parameter-reading period by the solutions of the present application is not increased.

The parallel processing device may have multiple modes of the particular implementations. For example, in a particular embodiment of the present application, taking into consideration that all of an MCU (Micro Controller Unit, or micro-controlling unit), a CPLD (Complex Programmable Logic Device) and an FPGA (Field-Programmable Gate Array) have the capacity of realizing multithreading, in a particular embodiment of the present application, the parallel processing device may be a parallel processing device based on a micro-controlling unit, or be a parallel processing device based on a Field-Programmable Gate Array, or be a parallel processing device based on a Complex Programmable Logic Device. For example, the first controller described in the following embodiments may particularly be an MCU, or a CPLD, or an FPGA. Likewise, the second controllers described in the following embodiments may particularly be MCUs, or CPLDs, or FPGAs.

Furthermore, the parallel processing device may be embodied as one single chip, and may also be embodied as a plurality of chips. Both of the two modes have advantages, and the two types of embodiments will be described in detail subsequently.

Step S303: at a second stage of each of the parameter-reading periods, sending the temperature data of the components the component types of which are a graphics processor to the baseboard management controller.

After the parallel processing device, at the first stage, reads simultaneously the respective temperature data of the components of the quantity N by using threads of the quantity N of the parallel processing device in a parallel-reading mode, because the GPU (Graphics Processing Unit, or graphics processor) is a component having a high temperature sensitivity, and over-temperature very easily happens in it, in the solutions of the present application, specially, at the second stage of each of the parameter-reading periods, the parallel processing device sends the temperature data of the components the component types of which are a graphics processor to the baseboard management controller. In other words, the temperature data of the GPUs among the components of the quantity N are sent to the baseboard management controller preferentially, so that the baseboard management controller can timely acquire the temperature data of the GPUs and accordingly perform the temperature controlling, which facilitates to ensure the stability of the temperatures of the GPUs.

Step S304: at a third stage of each of the parameter-reading periods, sending the temperature data of the components the component types of which are not a graphics processor to the baseboard management controller, whereby the baseboard management controller controls the temperature of the server based on the respective temperature data of the components of the quantity N.

After the sending of the temperature data of the GPUs has been completed, the process may enter the third stage of each of the parameter-reading periods. At this stage, the parallel processing device may send the temperature data of the components other than the GPUs to the baseboard management controller, whereby the baseboard management controller controls the temperature of the server based on the respective temperature data of the components of the quantity N.

The temperature controlling over the server by the baseboard management controller based on the respective temperature data of the components of the quantity N may have multiple modes of the particular implementations, which may be configured and adjusted according to practical demands, and do not affect the implementation of the present application. For example, at any moment, when the baseboard management controller has determined over-temperature of a certain component, the baseboard management controller may immediately control to increase the rotational speed of the relevant fan, so as to reduce the temperature of that component.

Regarding the temperature datum of any one of the components, the particular contents contained by the temperature datum of the component may also be configured and adjusted according to practical demands. Usually it contains the temperature of the component, and, in some occasions, may also have the temperature data in other aspects of the component. For example, the magnitude of the load of the component may also be considered as a reflection of the temperature of the component, and thus may also be used as the temperature datum of the component. Certainly, the configuring of the particular contents contained by the temperature datum is usually required to match the relevant algorithm used in the temperature controlling by the baseboard management controller, to realize the temperature controlling over the server, to ensure that all of the components operate within the suitable temperature ranges.

In a particular embodiment of the present application, the parallel processing device comprises one single first controller having at least threads of the quantity N.

As described above, the parallel processing device may be embodied as one single chip, and may also be embodied as a plurality of chips. In the present embodiment, the parallel processing device is formed by one single controller, i.e., embodied as one single chip, which controller is referred to as the first controller.

When the parallel processing device is formed by the first controller, it is required that the first controller has threads of at least the quantity N. By using the present embodiment, the time consumption on the reading of the temperature data may be highly reduced. The first controller is usually connected to the components of the quantity N by using I2C buses of groups of the quantity N that operate independently.

Optionally, in a particular embodiment of the present application, the first controller has a first interface and a second interface that are for connecting the baseboard management controller;
correspondingly, the step S303 particularly comprises:
at the second stage of each of the parameter-reading periods, via the first interface of the first controller, sending the temperature data of the components the component types of which are a graphics processor to the baseboard management controller; and
correspondingly, the step described in the step S304 of, at the third stage of each of the parameter-reading periods, sending the temperature data of the components the component types of which are not a graphics processor to the baseboard management controller may particularly comprise:
at the third stage of each of the parameter-reading periods, via the second interface of the first controller, sending the temperature data of the components the component types of which are not a graphics processor to the baseboard management controller.

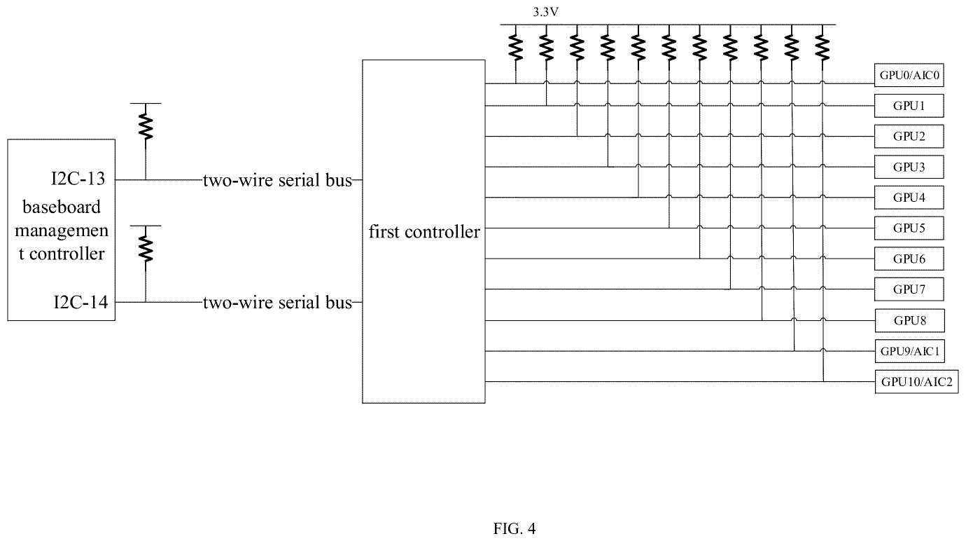

In the present embodiment, it is taken into consideration that, for a certain back panel, the baseboard management controller usually reserves one or two channels of the I2C, to read the temperature data of the components at the back panel, and, in the solutions of the present application, it is required to timely send the temperature data of the GPUs to the baseboard management controller. Therefore, in the present embodiment, the first controller has a first interface and a second interface that are for connecting the baseboard management controller. FIG. 4 shows the present embodiment. In other words, in FIG. 4, the parallel processing device particularly employs the first controller, and the first controller is connected to the baseboard management controller via 2 channels of the I2C buses, wherein one of the channels uses the first interface to connect the BMC, and is labeled as I2C-13 in FIG. 4, and the other channel uses the second interface to connect the BMC, and is labeled as I2C-14 in FIG. 4.

Because in the present embodiment it is merely required to use the first controller, within each of the parameter-reading periods, the BMC sequentially polls I2C-13 and I2C-14, which particularly comprises, at the second stage of each of the parameter-reading periods, reading the temperature data of the GPUs by using I2C-13. At this point, the first controller may, via the first interface of the first controller, send the temperature data of the components the component types of which are a GPU to the BMC.

Moreover, the BMC may, at the third stage of each of the parameter-reading periods, read by using I2C-14. At this point, the first controller may, via the second interface of the first controller, send the temperature data of the components the component types of which are not a graphics processor to the BMC.

Furthermore, it should also be noted that, in the embodiment of FIG. 4, the BMC is connected to the first controller via 2 channels of the I2C buses, wherein one of the channels of the I2C buses is dedicated to receiving the temperature data of the GPUs sent by the first controller, and the other channel of the I2C buses is dedicated to receiving the temperature data of the components of the other types sent by the first controller. If, in some occasions, the BMC reserves merely 1 channel of the I2C buses connected to the first controller, then in this case the first controller is merely required to be connected to the BMC via one single interface, and accordingly the temperature data of the components of all of the types are sent to the BMC via that interface. Certainly, in practical applications, what is usually employed is the embodiment in which the BMC reserves 2 channels of the I2C buses as in the present embodiment. That is because the messages used by the components of the different types for the temperature data transmission have certain differences, and if all of the components of the different types are sent to the BMC via one single channel of the I2C bus, the configuring of that channel is complicated, and it is required to set a priority for the temperature data of the GPUs. However, when the present embodiment of the present application is employed, the transmission of the temperature data of the GPUs is realized by using one dedicated channel, and the BMC is merely required to preferentially read the temperature data of the GPUs via that channel each time, which preferentially ensures the transmission efficiency of the temperature data of the GPUs, and is easy to design.

In a particular embodiment of the present application, among the components of the quantity N, the component types other than a graphics processor have a quantity of K, wherein K is a positive integer not less than 2, and the third stage of each of the parameter-reading periods is divided into sub-stages of the quantity K, wherein i is a positive integer and 1≤i≤K; and
correspondingly, the step of, at the third stage of each of the parameter-reading periods, via the second interface of the first controller, sending the temperature data of the components the component types of which are not a graphics processor to the baseboard management controller may particularly comprise:
at an i-th sub-stage of the third stage of each of the parameter-reading periods, via the second interface of the first controller, sending the temperature datum of an i-th type of the components the component types of which are not a graphics processor to the baseboard management controller.

In the present embodiment, it is taken into consideration that, when the first controller is sending the temperature data of the components to the BMC, the temperature data of the components of the same type may be completely sent altogether. For example, in the above example, the first interface of the first controller is dedicated to transmitting the temperature data of the GPUs. Therefore, when the BMC, at the second stage of each of the parameter-reading periods, is reading by using I2C-13, the first controller may, via the first interface of the first controller, send the temperature data of the GPUs to the BMC altogether.

Moreover, when the BMC, at the third stage of each of the parameter-reading periods, is reading by using I2C-14, because the component types other than the GPUs might be one or more types, it is required to send them at different sub-stages according to the different component types. In other words, as described in the present embodiment, at the i-th sub-stage of the third stage of each of the parameter-reading periods, via the second interface of the first controller, the temperature datum of an i-th type of the components the component types of which are not a GPU are sent to the baseboard management controller.

Taking Table 1 as an example for the description, table 1 is a table of comparison between 3 different examples of the embodiment of FIG. 4 and a conventional solution.

TABLE 1

| conventional architecture | | 100 | | | | | | | | | | |
|---|---|---|---|---|---|---|---|---|---|---|---|---|
| | | | 100 | | | | | | | | | |
| | | | | 100 | | | | | | | | |
| | | | | | 100 | | | | | | | |
| | | | | | | 100 | | | | | | |
| | | | | | | | 100 | | | | | |
| | | | | | | | | 100 | | | | |
| | | | | | | | | | 100 | | | |
| | | | | | | | | | | 100 | | |
| | | | | | | | | | | | 100 | |
| | | | | | | | | | | | | 100 |
| Example 1 | the first stage | 100 | | | | | | | | | | |
| | reading I2C-13 | | 5 | | | | | | | | | |
| | reading I2C-14 | | 5 | | | | | | | | | |
| Example 2 | the first stage | 100 | | | | | | | | | | |
| | reading I2C-13 | | 5 | | | | | | | | | |
| | reading I2C-14 | | 5 | | | | | | | | | |
| Example 3 | the first stage | 100 | | | | | | | | | | |
| | reading I2C-13 | | 5 | | | | | | | | | |
| | reading I2C-14 | | 5 | | | | | | | | | |
| | reading I2C-14 | | 5 | | | | | | | | | |
| | reading I2C-14 | | 5 | | | | | | | | | |

All of the units of the numerical values representing time consumptions in Table 1 are milliseconds. It can be seen that, in the conventional solution, when the BMC sequentially polls the 11 PCIe cards, 11×100=1100 ms is required before the temperature data of all of the 11 PCIe cards can be obtained.

In Example 1 in Table 1, it is assumed that the first controller in FIG. 4 is connected to 10 GPUs and 1 component of a non-GPU type, wherein the 10 GPUs are, for example, GPU0 to GPU9 in FIG. 4, and the 1 component of the non-GPU type is, for example, AIC2 in FIG. 4, wherein the AIC is Add-In Card (expansion board). In the present application, AIC is used to represent a component of a non-GPU type, which, particularly, for example, may be a network card, an RAID (Redundant Arrays of Independent Disks) card, an HCA (Host Channel Adapter) card and an HBA (Host Bus Adapter) card.

In Example 1 in Table 1, the first stage of the parameter-reading period consumes 100 ms. Within the 100 ms, the first controller acquires all of the temperature data of the 11 PCIe cards. The second stage consumes 5 ms. At this point, the BMC reads I2C-13, i.e., reading the first interface of the first controller, so that the BMC can obtain the temperature data of the GPUs altogether. The third stage consumes 5 ms. At this point, the BMC reads I2C-14, i.e., reading the second interface of the first controller, so that the BMC can obtain the temperature datum of the AIC2. It can be seen that, in Example 1, the parameter-reading period is totally 110 milliseconds, and, as compared with the conventional architecture, (1100−110)/1100=90%. In other words, the efficiency can be increased by approximately 90%; in other words, the time consumption is reduced by 90% of the original time consumption.

In Example 2 in Table 1, it is assumed that the first controller in FIG. 4 is connected to 9 GPUs and 3 components of a non-GPU type, wherein the 9 GPUs are, for example, GPU1 to GPU8 in FIG. 4, and the 3 components of the non-GPU type are AIC0, AIC1 and AIC2 in FIG. 4. Furthermore, it is assumed that AIC0, AIC1 and AIC2 are components of the same type; for example, all of them are identical RAID cards.

In Example 2 in Table 1, the first stage of the parameter-reading period consumes 100 ms. Within the 100 ms, the first controller acquires all of the temperature data of the 11 PCIe cards. The second stage consumes 5 ms. At this point, the BMC reads I2C-13, i.e., reading the first interface of the first controller, so that the BMC can obtain the temperature data of the 9 GPUs altogether. Because AIC0, AIC1 and AIC2 are components of the same type, the third stage of Example 2 consumes 5 ms. At this point, the BMC reads I2C-14, i.e., reading the second interface of the first controller, so that the BMC can obtain the temperature data of AIC0, AIC1 and AIC2 altogether. In Example 2, the parameter-reading period is totally 110 milliseconds, and, as compared with the conventional architecture, (1100−110)/1100=90%. In other words, the efficiency can be increased by approximately 90%.

In Example 3 in Table 1, it is assumed that the first controller in FIG. 4 is connected to 9 GPUs and 3 components of a non-GPU type, wherein the 9 GPUs are, for example, GPU1 to GPU8 in FIG. 4, and the 3 components of the non-GPU type are AIC0, AIC1 and AIC2 in FIG. 2. As different from Example 2, in Example 3, it is assumed that AIC0, AIC1 and AIC2 are components of different types.

In Example 3 in Table 1, the first stage and the second stage of the parameter-reading period are the same as those of Example 2, and are not described repeatedly. Because AIC0, AIC1 and AIC2 are components of different types, the third stage of Example 3 consumes 3×5 ms; in other words, the third stage requires 15 ms. At this point, the BMC reads I2C-14, i.e., reading the second interface of the first controller, to obtain sequentially the temperature data of AIC0, AIC1 and AIC2. In Example 3, the parameter-reading period is totally 120 milliseconds, and, as compared with the conventional architecture, (1100−120)/1100≈89%. In other words, the efficiency can be increased by approximately 89%; in other words, the time consumption is reduced by 89% of the original time consumption.

In a particular embodiment of the present application, the parallel processing device comprises second controllers of a quantity M, and the total quantity of the threads that the second controllers of the quantity M have is greater than or equal to N, wherein M is a positive integer not less than 2.

As described above, the parallel processing device may be embodied as one single chip, and may also be embodied as a plurality of chips. Furthermore, the parallel processing device embodied as one single chip has been described in detail above. In the present embodiment, the parallel processing device is embodied as a plurality of chips. In other words, the parallel processing device comprises controllers of a quantity M, and all of the controllers of the quantity M are referred to as second controllers, wherein M is a positive integer not less than 2. Because the second controllers are of the quantity M, it is required that the total quantity of the threads that the second controllers of the quantity M have is greater than or equal to N.

When the second controllers of the quantity M are employed, it can be understood that any one of the second controllers is connected to at least one of the components of the quantity N, and any one of the components of the quantity N is connected to at most one of the second controllers.

In the above embodiments employing the first controller, because it is required to connect one single chip to the components of the quantity N, there is a high requirement on the room; in other words, a continuous area of the circuit board is required for the deployment of the first controller. Certainly, in such a mode, the wiring is simpler. However, the present embodiment means that the second controllers of the quantity M embody the parallel processing device in a distributed mode. The second controllers of the quantity M may be arranged in a distributed mode, and therefore a continuous area of the circuit board is not required, which has a lower requirement on the circuit board, but increases the overall complexity of the wiring.

In a particular embodiment of the present application, all of the device models of the second controllers of the quantity M are the same, each of the second controllers has threads of a quantity a, wherein a is a positive integer and a×M≥N, and each of the second controllers has a first interface and a second interface that are for connecting the baseboard management controller.

As described above, the baseboard management controller usually reserves one or two channels of the I2C, and, in the solutions of the present application, it is required to timely send the temperature data of the GPUs to the baseboard management controller. Therefore, regarding the present embodiment employing the second controllers of the quantity M, each of the second controllers is provided with a first interface and a second interface that are for connecting the baseboard management controller. By employing such a configuration, for each of the second controllers, one dedicated channel of I2C may be used to realize the transmission of the temperature data of the GPUs connected to that second controller, to ensure the transmission efficiency of the temperature data of the GPUs.

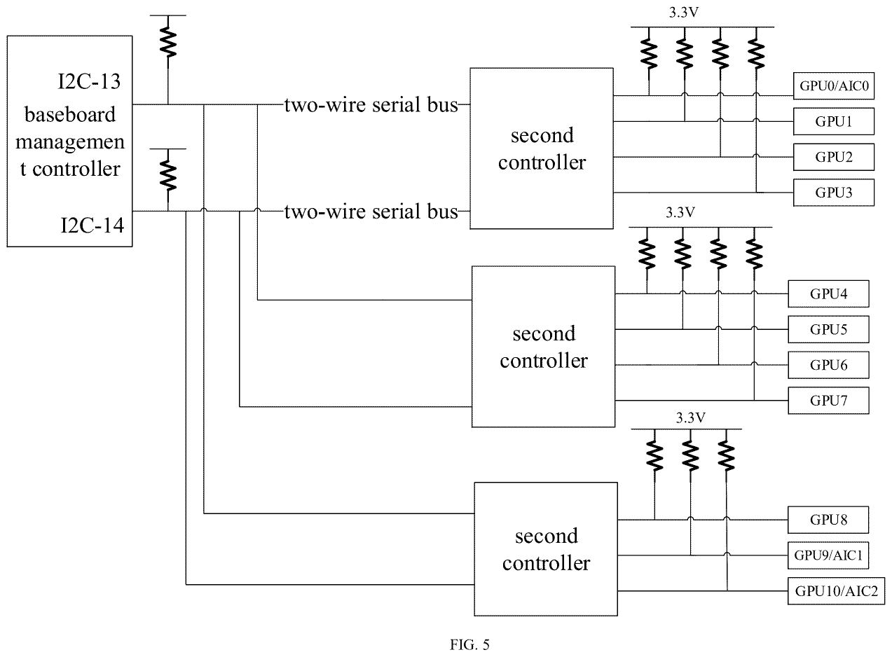

FIG. 5 shows 3 second controllers, i.e., M=3, and each of the second controllers may be connected to at most 4 PCIe components.

Furthermore, in the present embodiment, all of the device models of the second controllers of the quantity M are the same, and each of the second controllers has threads of a quantity a. That is because it is taken into consideration that, when the present embodiment is employed, that facilitates expansion, to reduce the workload of the firmware adaptation of the working personnel. For example, in the above occasion of FIG. 4, 11 components are externally connected. Therefore, it is required to provide a first controller having threads of at least the quantity N, and the I2C buses of groups of the quantity N that independently operate are used to connect the 11 components. Assuming that, in the subsequent operation process, 5 components are added, the first controller cannot satisfy the demand, and therefore the working personnel are required to redesign a new first controller having more groups of independent I2Cs.

However, taking FIG. 5 as an example, because all of the device models of the second controllers of the quantity M are the same, if 5 components are added, then it is merely required to, on the basis of FIG. 5, add 1 completely the same second controller, and cause each of the second controllers to be connected to 4 components. As a result, the working personnel are not required to redesign the firmware, and it is merely required to use 1 more second controller of the same model, whereby the present embodiment has a very high flexibility in implementation.

In a particular embodiment of the present application, the step S302 may particularly comprise:
at the first stage of each of the parameter-reading periods, by each of the second controllers, reading simultaneously the respective temperature data of the components connected to the second controller by using the threads of the quantity a of the second controller in the parallel-reading mode.

In the present embodiment, because the solution of the second controllers of the quantity M is employed, at the first stage of each of the parameter-reading periods, each of the second controllers may read simultaneously the respective temperature data of the components connected to the second controller by using the threads of the quantity a of the second controller in the parallel-reading mode. For example, in practical applications, because usually the I2C buses are used for the connection, each of the second controllers may be connected to components of at most the quantity a via the I2C buses of the group a that independently operate, thereby acquiring simultaneously the respective temperature data of the components connected to the second controller.

In a particular embodiment of the present application, the second stage is divided into sub-stages of the quantity M, and j is a positive integer and 1≤j≤M; and
the step S303 may particularly comprise:
at a j-th sub-stage of the second stage of each of the parameter-reading periods, by a j-th second controller among the second controllers of the quantity M, via the first interface of the j-th second controller, sending the temperature data of the components the component types of which are a graphics processor that are connected to the j-th second controller to the baseboard management controller.

In the above embodiments, because the parallel processing device is embodied as one single controller, at the second stage, the first controller may send the temperature data of the GPUs directly to the BMC. In the present embodiment, the parallel processing device is embodied as the second controllers of the quantity M, the BMC cannot simultaneously communicate with the second controllers of the quantity M, and each of the second controllers might be connected to the GPUs. Therefore, in the present embodiment, the BMC requires, at the second stage, polling the second controllers of the quantity M. In other words, the second stage is required to be divided into sub-stages of the quantity M, so that at the j-th sub-stage of the second stage of each of the parameter-reading periods, the j-th second controller among the second controllers of the quantity M sends the temperature data of the GPUs acquired by it to the BMC. Certainly, if a certain second controller is not connected to any GPU, then the BMC omits that second controller at the second stage.

In a particular embodiment of the present application, among the components of the quantity N, the component types other than a graphics processor have a quantity of K, wherein K is a positive integer not less than 2, the third stage of each of the parameter-reading periods is divided into rounds of the quantity K, and each of the rounds is divided into sub-stages of the quantity M, wherein i is a positive integer and 1≤i≤K, and j is a positive integer and 1≤j≤M; and

the step described in the step S304 of, at the third stage of each of the parameter-reading periods, sending the temperature data of the components the component types of which are not a graphics processor to the baseboard management controller may particularly comprise:
at a j-th sub-duration of an i-tb round of the third stage of each of the parameter-reading periods, by a j-th second controller among the second controllers of the quantity M, via the second interface of the j-th second controller, sending the temperature datum of an i-th type of the components the component types of which are not a graphics processor that are connected to the j-th second controller to the baseboard management controller.

In the present embodiment, because the solution of the second controllers of the quantity M is employed, and the component types other than the GPUs might be multiple types, the third stage of each of the parameter-reading periods is required to be divided into rounds of the quantity K, and each of the rounds is divided into sub-stages of the quantity M, to realize the transmission of the temperature data of the different component types of the different second controllers.

Taking Table 2 as an example for the description, table 2 is a table of comparison between 3 different examples of the embodiment of FIG. 5 and a conventional solution.

TABLE 2

| conventional architecture | | 100 | | | | | | | | | | |
|---|---|---|---|---|---|---|---|---|---|---|---|---|
| | | | 100 | | | | | | | | | |
| | | | | 100 | | | | | | | | |
| | | | | | 100 | | | | | | | |
| | | | | | | 100 | | | | | | |
| | | | | | | | 100 | | | | | |
| | | | | | | | | 100 | | | | |
| | | | | | | | | | 100 | | | |
| | | | | | | | | | | 100 | | |
| | | | | | | | | | | | 100 | |
| | | | | | | | | | | | | 100 |
| Example 1 | the first stage | 100 | | | | | | | | | | |
| | reading I2C-13 | | 5 | | | | | | | | | |
| | reading I2C-13 | | 5 | | | | | | | | | |
| | reading I2C-13 | | 5 | | | | | | | | | |
| | reading I2C-14 | | 5 | | | | | | | | | |
| Example 2 | the first stage | 100 | | | | | | | | | | |
| | reading I2C-13 | | 5 | | | | | | | | | |
| | reading I2C-13 | | 5 | | | | | | | | | |
| | reading I2C-13 | | 5 | | | | | | | | | |
| | reading I2C-14 | | 5 | | | | | | | | | |
| | reading I2C-14 | | 5 | | | | | | | | | |
| Example 3 | the first stage | 100 | | | | | | | | | | |
| | reading I2C-13 | | 5 | | | | | | | | | |
| | reading I2C-13 | | 5 | | | | | | | | | |
| | reading I2C-13 | | 5 | | | | | | | | | |
| | reading I2C-14 | | 5 | | | | | | | | | |
| | reading I2C-14 | | 5 | | | | | | | | | |
| | reading I2C-14 | | 5 | | | | | | | | | |

All of the units of the numerical values representing time consumptions in Table 2 are milliseconds. It can be seen that, in the conventional solution, when the BMC sequentially polls the 11 PCIe cards, 11×100=1100 ms is required before the temperature data of all of the 11 PCIe cards can be obtained.

In Example 1 in Table 2, it is assumed that the 3 second controllers in FIG. 5 are connected to totally 10 GPUs and 1 component of a non-GPU type, wherein the 10 GPUs are GPU0 to GPU9 in FIG. 5, and the 1 component of the non-GPU type is, for example, AIC2 in FIG. 5.

In Example 1 in Table 2, the first stage of the parameter-reading period consumes 100 ms. Within the 100 ms, each of the 3 second controllers acquires the temperature data of the components connected to the second controller. The second stage is divided into 3 sub-stages. Firstly, the BMC reads I2C-13, at which point what is polled is the first interface of the first second controller in FIG. 5, so that the BMC can obtain the temperature data of the GPUs connected to the first second controller altogether. Subsequently, the BMC reads I2C-13, at which point what is polled is the first interface of the second second controller in FIG. 5, so that the BMC can obtain the temperature data of the GPUs connected to the second second controller altogether. Finally, the BMC reads I2C-13, at which point what is polled is the first interface of the third second controller in FIG. 5, so that the BMC can obtain the temperature data of the GPUs connected to the third second controller altogether. So far, the second stage of the parameter-reading period ends.

In Example 1 in Table 2, there is merely one component of a non-GPU type. From the information obtained above in the step S301, it can be known that that component is connected to the third second controller. Accordingly, at this point, at the third stage of the parameter-reading period, the BMC reads I2C-14, particularly, reading the second interface of the third second controller, so that the BMC can obtain the temperature datum of the AIC2. It can be seen that, in Example 1, the parameter-reading period is totally 120 milliseconds, and, as compared with the conventional architecture, (1100−120)/1100≈89%. In other words, the efficiency can be increased by approximately 89%; in other words, the time consumption is reduced by 89% of the original time consumption.

In Example 2 in Table 2, it is assumed that the 3 second controllers in FIG. 5 are connected to 9 GPUs and 3 components of a non-GPU type, wherein the 9 GPUs are, for example, GPU1 to GPU8 in FIG. 5, and the 3 components of the non-GPU type are AIC0, AIC1 and AIC2 in FIG. 5. Furthermore, it is assumed that AIC0, AIC1 and AIC2 are components of the same type; for example, all of them are identical RAID cards.

In Example 2 in Table 2, the first stage of the parameter-reading period consumes 100 ms. Within the 100 ms, each of the 3 second controllers acquires the temperature data of the components connected to the second controller. The second stage is divided into 3 sub-stages. They, as the same as Example 1, also consumes 15 ms, and are not described repeatedly.

In Example 2 in Table 2, there are 3 components of a non-GPU type. From the information obtained above in the step S301, it can be known that one of the 3 components of a non-GPU type is connected to the first second controller, and the other two are connected to the third second controller. Accordingly, at this point, at the third stage of the parameter-reading period, the BMC reads I2C-14, and may firstly poll the second interface of the first second controller, and subsequently poll the second interface of the third second controller, which requires totally 10 ms. It can be seen that, in Example 2 in Table 2, the parameter-reading period is totally 125 milliseconds, and, as compared with the conventional architecture, (1100−125)/1100≈88.6%. In other words, the efficiency can be increased by approximately 88.6%.

In Example 3 in Table 2, it is assumed that the 3 second controllers in FIG. 5 are connected to 9 GPUs and 3 components of a non-GPU type, wherein the 9 GPUs are, for example, GPU1 to GPU8 in FIG. 5, and the 3 components of the non-GPU type are AIC0, AIC1 and AIC2 in FIG. 5. Furthermore, it is assumed that AIC0, AIC1 and AIC2 are components of different types.

In Example 3 in Table 2, the first stage and the second stage of the parameter-reading period are the same as those of Example 2 in Table 2, and are not described repeatedly. Because AIC0, AIC1 and AIC2 are components of different types, and the BMC can know that one of the 3 components of a non-GPU type is connected to the first second controller, and the other two are connected to the third second controller, at the first sub-duration of the first round of the third stage of the parameter-reading period, the BMC reads I2C-14, and may poll the second interface of the first second controller, thereby reading the temperature datum of AIC0. Because there is not a component of the same type, the first round of the third stage ends. Subsequently, the process may directly enter the third sub-duration of the second round of the third stage. At this point, the BMC reads I2C-14, and may poll the second interface of the third second controller, thereby reading the temperature datum of AIC1. Because there is not a component of the same type, the second round of the third stage ends. Finally, the process may directly enter the third sub-duration of the third round of the third stage. At this point, the BMC reads I2C-14, and may poll the second interface of the third second controller, thereby reading the temperature datum of AIC2. Because there is not a component of the same type, the third round of the third stage ends. It can be seen that, in this example, the third stage requires totally 15 ms. It can be seen that, in Example 3 in Table 2, the parameter-reading period is totally 130 milliseconds, and, as compared with the conventional architecture, (1100−130)/1100≈88%. In other words, the efficiency can be increased by approximately 88.6%.

It can be understood that all of the sub-stages and sub-durations described above in the present application are merely intended to distinguish the temperature data of the components of the different types sent by the different controllers, and do not mean that within each of the sub-stages or sub-durations there is a temperature datum required to be sent to the BMC. Especially, when the embodiment of the second controllers of the quantity M is employed, the component types connected to the different second controllers are not necessarily completely the same. Regarding a sub-stage or sub-duration when no temperature datum is required to be sent, it is merely required to be directly omitted. For example, in Example 3 in the above Table 2, the component types other than the GPU are totally 3, i.e., K=3, and the quantity of the second controllers is 3, i.e., M=3. Therefore, at the third stage, theoretically there are at most 9 sub-durations when it is required to send the temperature data to the BMC. However, in Example 3 in the above Table 2, because the components other than the GPU are merely totally 3, the third stage ends after merely 3 sub-durations.

Furthermore, from the examples of Table 1 and Table 2, it can be seen that, no matter whether one single controller or a plurality of controllers are used to embody the parallel processing device, both of them may effectively increase the efficiency, i.e., effectively reducing the time consumption on the reading of the temperature data by the BMC. Certainly, especially, when the embodiment of one single controller is employed, the efficiency increase is slightly greater than that of the embodiment of a plurality of controllers.

In a particular embodiment of the present application, the method may further comprise:
in response to a failure signal sent by any one of the components having been received, pausing the sending of the temperature data of a current stage, sending the failure signal to the baseboard management controller, and after the sending of the failure signal has been completed, continuing the sending of the temperature data of the current stage.

In the present embodiment, it is taken into consideration that the parallel processing device according to the present application may further be configured for receiving failure signals sent by the components. If the failure signal sent by any one of the components has been received, in order to ensure the priority of the sending of the failure signal, in the present embodiment, the method may comprise pausing the sending of the temperature data of a current stage, sending the failure signal to the baseboard management controller, and after the sending of the failure signal has been completed, continuing the sending of the temperature data of the current stage.

In the technical solutions according to the embodiments of the present application, it is taken into consideration that the reason why the collection of the temperature data by the baseboard management controller has a long time consumption is that the baseboard management controller polls the components and the components have a high quantity. Accordingly, the solutions of the present application specially provide the parallel processing device connected to the baseboard management controller, to assist the baseboard management controller in realizing the acquirement of the temperature data and thus realizing the temperature controlling over the server. Particularly, the parallel processing device is connected to components of a quantity N, and at the first stage of each of the parameter-reading periods, the parallel processing device reads simultaneously the respective temperature data of the components of the quantity N by using threads of the quantity N of the parallel processing device in a parallel-reading mode. It can be seen that, no matter whether the quantity N is a high quantity or a low quantity, because the parallel processing device reads simultaneously the respective temperature data of the components of the quantity N by using threads of the quantity N of the parallel processing device in a parallel-reading mode, even if the components have a high quantity, the time consumption at the first stage of the parameter-reading period is not increased. Moreover, at the second stage and the third stage, the parallel processing device may send the respective temperature data of the components of the quantity N to the baseboard management controller, whereby the baseboard management controller controls the temperature of the server. Both of the second stage and the third stage have very short time consumptions. Furthermore, in the present application, it is taken into consideration that the components of the different types are sensitive to the temperature differently, and, as compared with the other components, a graphics processor is a component having a high temperature sensitivity. Therefore, in the solutions of the present application, preferentially, at the second stage, all of the temperature data of the components the component types of which are a graphics processor are sent to the baseboard management controller, so that the baseboard management controller can timely acquire the temperature data of the graphics processors and accordingly perform the temperature controlling, which facilitates to ensure the stability of the temperatures of the graphics processors. Certainly, because the solutions of the present application require distinguishing the component types, it is required to, after the server has been powered on, determine the respective component types of all of the components of the quantity N and send the respective component types to the baseboard management controller. As compared with the conventional solutions, that operation is an additional operation and has certain time consumption, but it is merely required to be executed one time after the server has been powered on, and does not affect the parameter-reading periods in the subsequent operation process of the server.

In conclusion, the solutions of the present application may effectively shorten the time consumption on the acquirement of the temperature data of the components by the baseboard management controller, and may timely acquire the temperature datum of the graphics processor, which has a high temperature sensitivity. Therefore, the solutions of the present application may realize the temperature controlling over the server more precisely and effectively, to ensure the service life and the reliability of the server.

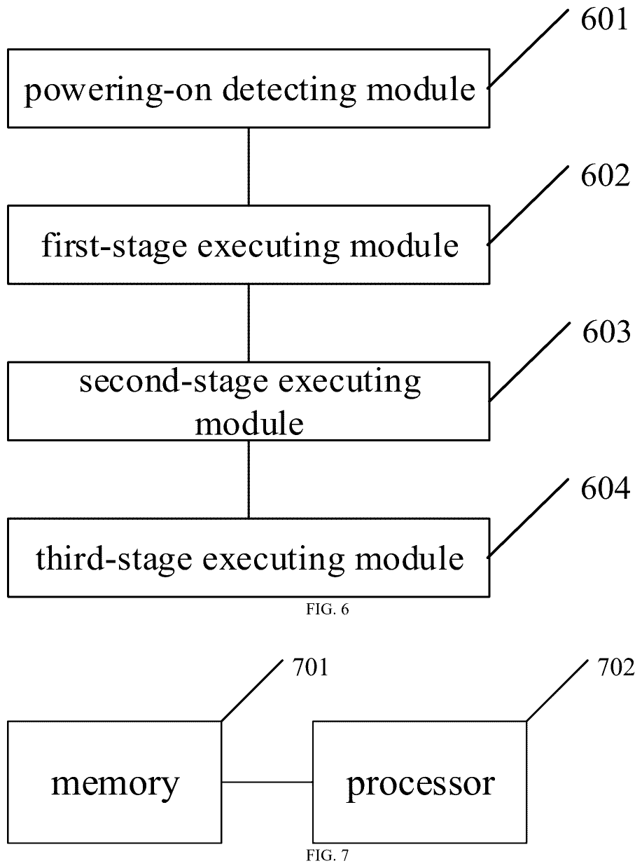

As corresponding to the above process embodiments, an embodiment of the present application further provides a system for controlling temperature of a server. Referring to FIG. 2, the system may comprise a baseboard management controller and a predetermined parallel processing device connected to the baseboard management controller, and the parallel processing device is connected to components of a quantity N. Referring to FIG. 6, the parallel processing device may comprise:

a powering-on detecting module 601 configured for, after the server has been powered on, determining respective component types of all of the components of the quantity N and sending the respective component types to the baseboard management controller;

a first-stage executing module 602 configured for, at a first stage of each of parameter-reading periods, reading simultaneously respective temperature data of the components of the quantity N by using threads of the quantity N of the parallel processing device in a parallel-reading mode;

a second-stage executing module 603 configured for, at a second stage of each of the parameter-reading periods, sending the temperature data of the components the component types of which are a graphics processor to the baseboard management controller; and

a third-stage executing module 604 configured for, at a third stage of each of the parameter-reading periods, sending the temperature data of the components the component types of which are not a graphics processor to the baseboard management controller, whereby the baseboard management controller controls the temperature of the server based on the respective temperature data of the components of the quantity N.

In a particular embodiment of the present application, the parallel processing device comprises one single first controller having at least threads of the quantity N.

In a particular embodiment of the present application, the first controller has a first interface and a second interface that are for connecting the baseboard management controller;
correspondingly, the second-stage executing module 603 is particularly configured for:
at the second stage of each of the parameter-reading periods, via the first interface of the first controller, sending the temperature data of the components the component types of which are a graphics processor to the baseboard management controller; and
correspondingly, the third-stage executing module 604 is particularly configured for:
at the third stage of each of the parameter-reading periods, via the second interface of the first controller, sending the temperature data of the components the component types of which are not a graphics processor to the baseboard management controller, whereby the baseboard management controller controls the temperature of the server based on the respective temperature data of the components of the quantity N.

In a particular embodiment of the present application, the component types other than a graphics processor have a quantity of K, wherein K is a positive integer not less than 2, and the third stage of each of the parameter-reading periods is divided into sub-stages of the quantity K, wherein i is a positive integer and 1≤i≤K; and
correspondingly, the third-stage executing module 604 is particularly configured for:
at an i-th sub-stage of the third stage of each of the parameter-reading periods, via the second interface of the first controller, sending the temperature datum of an i-th type of the components the component types of which are not a graphics processor to the baseboard management controller, whereby the baseboard management controller controls the temperature of the server based on the respective temperature data of the components of the quantity N.

In a particular embodiment of the present application, the parallel processing device comprises second controllers of a quantity M, a total quantity of threads that the second controllers of the quantity M have is greater than or equal to N, wherein M is a positive integer not less than 2, any one of the second controllers is connected to at least one instance of the components of the quantity N, and any one instance of the components of the quantity N is connected to at most one instance of the second controllers.

In a particular embodiment of the present application, all of device models of the second controllers of the quantity M are the same, each of the second controllers has threads of a quantity a, wherein a is a positive integer and a×M≥N, and each of the second controllers has a first interface and a second interface that are for connecting the baseboard management controller.

In a particular embodiment of the present application, the first-stage executing module 602 is particularly configured for:

at the first stage of each of the parameter-reading periods, by each of the second controllers, reading simultaneously the respective temperature data of the components connected to the second controller by using the threads of the quantity a of the second controller in the parallel-reading mode.

In a particular embodiment of the present application, the second stage is divided into sub-stages of the quantity M, and j is a positive integer and 1≤j≤M; and
correspondingly, the second-stage executing module 603 is particularly configured for:
at a j-th sub-stage of the second stage of each of the parameter-reading periods, by a j-th second controller among the second controllers of the quantity M, via the first interface of the j-th second controller, sending the temperature data of the components the component types of which are a graphics processor that are connected to the j-th second controller to the baseboard management controller.

In a particular embodiment of the present application, the component types other than a graphics processor have a quantity of K, wherein K is a positive integer not less than 2, the third stage of each of the parameter-reading periods is divided into rounds of the quantity K, and each of the rounds is divided into sub-stages of the quantity M, wherein i is a positive integer and 1≤i≤K, and j is a positive integer and 1≤j≤M; and
correspondingly, the third-stage executing module 604 is particularly configured for:
at a j-th sub-duration of an i-th round of the third stage of each of the parameter-reading periods, by a j-th second controller among the second controllers of the quantity M, via the second interface of the j-th second controller, sending the temperature datum of an i-th type of the components the component types of which are not a graphics processor that are connected to the j-th second controller to the baseboard management controller, whereby the baseboard management controller controls the temperature of the server based on the respective temperature data of the components of the quantity N.

In a particular embodiment of the present application, the parallel processing device is a parallel processing device based on a micro-controlling unit, or is a parallel processing device based on a Field-Programmable Gate Array, or is a parallel processing device based on a Complex Programmable Logic Device.

In a particular embodiment of the present application, the device further comprises:
a failure-signal processing module configured for, in response to a failure signal sent by any one of the components having been received, pausing the sending of the temperature data of a current stage, sending the failure signal to the baseboard management controller, and after the sending of the failure signal has been completed, continuing the sending of the temperature data of the current stage.

As corresponding to the above process embodiments and system embodiments, the embodiments of the present application further provide a device for controlling temperature of a server and a computer-readable storage medium, which may be used as reference with the above contents mutually.

Referring to FIG. 7, the device for controlling temperature of a server may comprise:
a memory 701 configured for storing a computer program; and
a processor 702 configured for executing the computer program to implement the steps of the method for controlling the temperature of the server according to any one of the above embodiments.

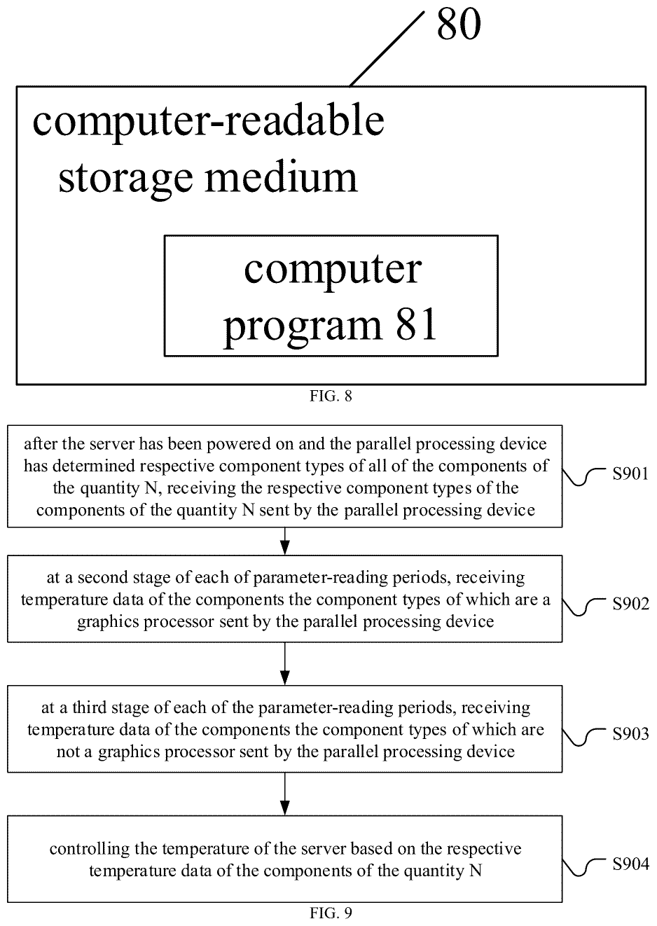

Referring to FIG. 8, the computer-readable storage medium 80 stores a computer program 81, and the computer program 81, when executed by a processor, implements the steps of the method for controlling the temperature of the server according to any one of the above embodiments. The computer-readable storage medium 80 described herein includes a Random Access Memory (RAM), an internal memory, a read-only memory (ROM), an electrically programmable ROM, an electrically erasable programmable ROM, a register, a hard disk, a removable disk, a CD-ROM, or a storage medium in any other form well known in the art.

Referring to FIG. 9, FIG. 9 is a flow chart of the implementation of the method for controlling temperature of a server according to the present application. The baseboard management controller is connected to the predetermined parallel processing device, the parallel processing device is connected to components of a quantity N, and the method for controlling the temperature of the server is applied in the baseboard management controller, and comprises:

Step S901: after the server has been powered on and the parallel processing device has determined respective component types of all of the components of the quantity N, receiving the respective component types of the components of the quantity N sent by the parallel processing device;

Step S902: at a second stage of each of parameter-reading periods, receiving temperature data of the components the component types of which are a graphics processor sent by the parallel processing device;

Step S903: at a third stage of each of the parameter-reading periods, receiving temperature data of the components the component types of which are not a graphics processor sent by the parallel processing device; and

Step S904: controlling the temperature of the server based on the respective temperature data of the components of the quantity N;
wherein at a first stage of each of the parameter-reading periods, the parallel processing device reads simultaneously the respective temperature data of the components of the quantity N by using threads of the quantity N of the parallel processing device in a parallel-reading mode.

It should also be noted that, in the present text, relation terms such as first and second are merely intended to distinguish one entity or operation from another entity or operation, and that does not necessarily require or imply that those entities or operations have therebetween any such actual relation or order. Furthermore, the terms “include”, “comprise” or any variants thereof are intended to cover non-exclusive inclusions, so that processes, methods, articles or devices that include a series of elements do not only include those elements, but also include other elements that are not explicitly listed, or include the elements that are inherent to such processes, methods, articles or devices. Unless further limitation is set forth, an element defined by the wording “comprising a . . . ” does not exclude additional same element in the process, method, article or device comprising the element.

A person skilled in the art can further understand that the units and the algorithm steps of the examples described with reference to the embodiments disclosed herein may be implemented by using electronic hardware, computer software or a combination thereof. In order to clearly explain the interchangeability between the hardware and the software, the above description has described generally the configurations and the steps of the examples according to the functions. Whether those functions are executed by hardware or software depends on the particular applications and the design constraints of the technical solutions. A person skilled in the art may employ different methods to implement the described functions with respect to each of the particular applications, but the implementations should not be considered as extending beyond the scope of the present application.

The principle and the embodiments of the present application are described herein with reference to the particular examples, and the description of the above embodiments is merely intended to facilitate to comprehend the technical solutions of the present application and their core concept. It should be noted that a person skilled in the art may make improvements and modifications on the present application without departing from the principle of the present application, and all of the improvements and modifications fall within the protection scope of the present application.

1. A method for controlling temperature of a server, wherein a baseboard management controller is connected to a predetermined parallel processing device, the parallel processing device is connected to components of a quantity N, and the method for controlling the temperature of the server is applied in the parallel processing device, and comprises:
after the server has been powered on, determining respective component types of all of the components of the quantity N and sending the respective component types to the baseboard management controller;
at a first stage of each of parameter-reading periods, reading simultaneously respective temperature data of the components of the quantity N by using threads of the quantity N of the parallel processing device in a parallel-reading mode;
at a second stage of each of the parameter-reading periods, sending the temperature data of the components the component types of which are a graphics processor to the baseboard management controller; and
at a third stage of each of the parameter-reading periods, sending the temperature data of the components the component types of which are not a graphics processor to the baseboard management controller, whereby the baseboard management controller controls the temperature of the server based on the respective temperature data of the components of the quantity N.

2. The method for controlling the temperature of the server according to claim 1, wherein the parallel processing device comprises one single first controller having at least threads of the quantity N.

3. The method for controlling the temperature of the server according to claim 2, wherein the first controller has a first interface and a second interface that are for connecting the baseboard management controller;
the step of, at the second stage of each of the parameter-reading periods, sending the temperature data of the components the component types of which are a graphics processor to the baseboard management controller comprises:
at the second stage of each of the parameter-reading periods, via the first interface of the first controller, sending the temperature data of the components the component types of which are a graphics processor to the baseboard management controller; and
the step of, at the third stage of each of the parameter-reading periods, sending the temperature data of the components the component types of which are not a graphics processor to the baseboard management controller comprises:
at the third stage of each of the parameter-reading periods, via the second interface of the first controller, sending the temperature data of the components the component types of which are not a graphics processor to the baseboard management controller.

4. The method for controlling the temperature of the server according to claim 3, wherein among the components of the quantity N, the component types other than a graphics processor have a quantity of K, wherein K is a positive integer not less than 2, and the third stage of each of the parameter-reading periods is divided into sub-stages of the quantity K, wherein i is a positive integer and 1≤i≤K; and
the step of, at the third stage of each of the parameter-reading periods, via the second interface of the first controller, sending the temperature data of the components the component types of which are not a graphics processor to the baseboard management controller comprises:
at an i-th sub-stage of the third stage of each of the parameter-reading periods, via the second interface of the first controller, sending the temperature datum of an i-th type of the components the component types of which are not a graphics processor to the baseboard management controller.

5. The method for controlling the temperature of the server according to claim 1, wherein the parallel processing device comprises second controllers of a quantity M, a total quantity of threads that the second controllers of the quantity M have is greater than or equal to N, wherein M is a positive integer not less than 2, any one of the second controllers is connected to at least one instance of the components of the quantity N, and any one instance of the components of the quantity N is connected to at most one instance of the second controllers.

6. The method for controlling the temperature of the server according to claim 5, wherein all of device models of the second controllers of the quantity M are the same, each of the second controllers has threads of a quantity a, wherein a is a positive integer and a×M≥N, and each of the second controllers has a first interface and a second interface that are for connecting the baseboard management controller.

7. The method for controlling the temperature of the server according to claim 6, wherein the step of, at the first stage of each of the parameter-reading periods, reading simultaneously the respective temperature data of the components of the quantity N by using the threads of the quantity N of the parallel processing device in the parallel-reading mode comprises:
at the first stage of each of the parameter-reading periods, by each of the second controllers, reading simultaneously the respective temperature data of the components connected to the second controller by using the threads of the quantity a of the second controller in the parallel-reading mode.

8. The method for controlling the temperature of the server according to claim 6, wherein the second stage is divided into sub-stages of the quantity M, and j is a positive integer and 1≤j≤M; and
the step of, at the second stage of each of the parameter-reading periods, sending the temperature data of the components the component types of which are a graphics processor to the baseboard management controller comprises:
at a j-th sub-stage of the second stage of each of the parameter-reading periods, by a j-th second controller among the second controllers of the quantity M, via the first interface of the j-th second controller, sending the temperature data of the components the component types of which are a graphics processor that are connected to the j-th second controller to the baseboard management controller.

9. The method for controlling the temperature of the server according to claim 6, wherein among the components of the quantity N, the component types other than a graphics processor have a quantity of K, wherein K is a positive integer not less than 2, the third stage of each of the parameter-reading periods is divided into rounds of the quantity K, and each of the rounds is divided into sub-stages of the quantity M, wherein i is a positive integer and 1≤i≤K, and j is a positive integer and 1≤j≤M; and
the step of, at the third stage of each of the parameter-reading periods, sending the temperature data of the components the component types of which are not a graphics processor to the baseboard management controller comprises:
at a j-th sub-duration of an i-th round of the third stage of each of the parameter-reading periods, by a j-th second controller among the second controllers of the quantity M, via the second interface of the j-th second controller, sending the temperature datum of an i-th type of the components the component types of which are not a graphics processor that are connected to the j-th second controller to the baseboard management controller.

10. The method for controlling the temperature of the server according to claim 1, wherein the parallel processing device is a parallel processing device based on a micro-controlling unit, or is a parallel processing device based on a Field-Programmable Gate Array, or is a parallel processing device based on a Complex Programmable Logic Device.

11. The method controlling the temperature of the server according to claim 1, wherein the method further comprises:
in response to a failure signal sent by any one of the components having been received, pausing the sending of the temperature data of a current stage, sending the failure signal to the baseboard management controller, and after the sending of the failure signal has been completed, continuing the sending of the temperature data of the current stage.

12. The method for controlling the temperature of the server according to claim 1, wherein the step of determining the respective component types of all of the components of the quantity N comprises:
by the parallel processing device, polling the components of the quantity N connected to the parallel processing device.

13. The method for controlling the temperature of the server according to claim 3, wherein the method further comprises:
in response to all of the temperature data of the components that are a graphics processor and the temperature data of the components that are not a graphics processor having been sent to the baseboard management controller via a single-channel I2C (Inter-Integrated Circuit) bus, configuring priorities of the temperature data of the components that are a graphics processor.

14. The method for controlling the temperature of the server according to claim 3, wherein the first interface is configured to be dedicated to transmitting altogether the temperature data of the components the component types of which are a graphics processor.

15. The method for controlling the temperature of the server according to claim 6, wherein each of the second controllers is configured for, by using one dedicated channel of I2C (Inter-Integrated Circuit), performing transmission of the temperature data of the components the component types of which are a graphics processor that are connected to the second controller.

16. The method for controlling the temperature of the server according to claim 1, wherein the parallel processing device is formed by one single chip or a plurality of chips.

17. (canceled)

18. A device for controlling temperature of a server, wherein the device comprises:
a memory configured for storing a computer program; and
a processor configured for executing the computer program to implement the steps of the method for controlling the temperature of the server according to claim 1.

19. A computer-readable storage medium, wherein the computer-readable storage medium stores a computer program, and the computer program, when executed by a processor, implements the steps of the method for controlling the temperature of the server according claim 1.

20. A method for controlling temperature of a server, wherein a baseboard management controller is connected to a predetermined parallel processing device, the parallel processing device is connected to components of a quantity N, and the method for controlling the temperature of the server is applied in the baseboard management controller, and comprises:
after the server has been powered on and the parallel processing device has determined respective component types of all of the components of the quantity N, receiving the respective component types of the components of the quantity N sent by the parallel processing device;
at a second stage of each of parameter-reading periods, receiving temperature data of the components the component types of which are a graphics processor sent by the parallel processing device;
at a third stage of each of the parameter-reading periods, receiving temperature data of the components the component types of which are not a graphics processor sent by the parallel processing device; and
controlling the temperature of the server based on the respective temperature data of the components of the quantity N;
wherein at a first stage of each of the parameter-reading periods, the parallel processing device reads simultaneously the respective temperature data of the components of the quantity N by using threads of the quantity N of the parallel processing device in a parallel-reading mode.

21. The method for controlling the temperature of the server according to claim 1, wherein the respective temperature data of the components of the quantity N include temperatures of the components of the quantity N and loads of the components of the quantity N.
